(19) United States
(12) Patent Application Publication
(10) Pub. No.: US 2012/0055542 A1
(43) Pub. Date: Mar. 8, 2012

(54) Photovoltaic cell

(75) Inventors: Chiung-Wei Lin, Taipei City (TW); Yi-Liang Chen, Taipei City (TW)

(73) Assignees: Tatung Company, Taipei (TW); Tatung University, Taipei (TW)

(21) Appl. No.: 12/929,451

(22) Filed: Jan. 26, 2011

(30) Foreign Application Priority Data
Sep. 3, 2010 (TW) 099129844

(51) Int. Cl. H01L 31/06

(52) U.S. Cl. 136/255

(57) ABSTRACT

A structure of photovoltaic cell for improving conversion efficiency has been disclosed, including a first bandgap layer, a second bandgap layer, a third bandgap layer, a back electrode and a finger electrode, wherein the first bandgap layer is a wafer while the second bandgap layer is a semiconductor film with a thickness of 1˜100 Å and a greater bandgap than one of the first bandgap layer, and the third bandgap layer comprises wide bandgap materials and a greater bandgap than one of the second bandgap layer. Thereby, the lattice mismatch of heterostructures between the first bandgap layer and the third bandgap layer may be solved by the second bandgap layer. Also, the carrier recombination within devices may be decreased and the output photocurrent may thus be enhanced to improve energy conversion efficiency.

### BACKGROUND OF THE INVENTION

1. Field of the Invention

The present invention relates to a photovoltaic cell and, more particularly, to a photovoltaic cell with a bandgap gradient.

2. Description of Related Art

Recently, renewable energy technologies have been promoted, and the industry mainly focuses on development of solar cells due to that solar cells may be used to supply energy in the future. Accordingly, solar cells for the development of solar energy are one of photovoltaic technologies having development potential in 21 century. FIG. 1 shows a conventional solar cell in a P-N junction structure, which includes: a finger electrode 10, a window layer 11, an N layer 13, a P-type silicon wafer 13 and a back electrode 14. The window layer 11 covers the surface of the N layer 12 to allow more incident photons to enter the interior of the solar cell. However, the inner N layer 12 is too thick and thus incident light cannot efficiently achieve the PN junction 121, resulting in loss of light. The large thickness of the N layer 12 and the increased defects cause the difficult movement and easy recombination of photo-generated carriers in the depletion region and thus the conversion efficiency of the solar cell is reduced.

In order to resolve the problem that the N layer is too thick in the conventional structure, a solar cell where the N layer is removed was suggested (see FIG. 2), which includes: a finger electrode 20, a window layer 21, a P-type silicon wafer 22 and a back electrode 23. The window layer 21 is made of a wide bandgap material and covers the p-type silicon wafer 22 to allow incident light to directly achieve the junction. Thereby, carriers can be generated in the absence of the N layer and loss of light caused by the great thickness of the N layer can be prevented. However, more interface defects are formed in the structure due to the large difference of lattice mismatch. During irradiation on the component, carriers generated in the built-in electric field of the PN junction mostly are recombined during output, resulting in nearly disappearance of photocurrent.

### SUMMARY OF THE INVENTION

In order to overcome the above-mentioned problems, one object of the present invention is to provide a photovoltaic cell, which uses a wide bandgap material to allow the transmission of most photons (i.e. almost no photons being absorbed by the wide bandgap material). That is, photons are gathered to a narrow bandgap layer so as to enhance the absorption of photons in the interface depletion region between the wide bandgap layer and the narrow bandgap layer and to resolve the problem that excessively large thickness of the N layer causes loss of light.

Another object of the present invention is to provide a photovoltaic cell in which the problem of hetrojunction lattice mismatch causing junction defects and recombination of carriers is overcome.

Thereby, the present invention provides a photovoltaic cell, including: a first bandgap layer, which is a silicon wafer and has a first surface and a second surface; a second bandgap layer, which is a semiconductor film with a thickness of 1˜100 Å and a greater bandgap than that of the first bandgap layer and is disposed on the first surface of the first bandgap layer; a third bandgap layer, which includes a wide bandgap material and a greater bandgap than that of the second bandgap layer and is disposed on the second bandgap layer; a back electrode, which is jointed to the second surface of the first bandgap layer; and a finger electrode, which is disposed on the third bandgap layer and jointed to the third bandgap layer.

According to one aspect of the present invention, the silicon wafer may be a P-type silicon wafer or a similar thereof but is not limited thereto. Also, an N-type silicon wafer may be used.

According to one aspect of the present invention, the semiconductor film may be an amorphous silicon film but is not limited thereto. Other similar films with a bandgap between those of the first bandgap layer and the third bandgap layer may be used.

According to one aspect of the present invention, the semiconductor film may be anyone of an intrinsic semiconductor, an N-type semiconductor and a P-type semiconductor.

According to one aspect of the present invention, the thickness of the second bandgap layer preferably ranges from 1 Å to 50 Å, and more preferably from 1 Å to 10 Å.

According to one aspect of the present invention, the wide bandgap material is a transparent conducting oxide (TCO). For example, the transparent conducting oxide includes, but is not limited to anyone of AZO, ITO, CTO, ZnO:Al, ZnGa₂O4, SnO₂:Sb, Ga₂O₃:Sn, AgInO₂:Sn, In₂O₃: Zn, CUAlO₂, LaCuOS, NiO, CuGaO₂ and SrCu₂O₂. Preferably, the transparent conducting oxide is AZO or ITO. More preferably, the transparent conducting oxide is AZO. According to one aspect of the present invention, a back surface field (BSF) is formed between the back electrode and the second surface of the first bandgap layer.

According to one aspect of the present invention, each bandgap layer in the photovoltaic cell is not particularly limited in bandgap energy, and may be modified according to the required purpose of the photovoltaic cell. Preferably, the bandgap energy of the first bandgap layer ranges from 1.1 eV to 1.7 eV, and the bandgap energy of the third bandgap layer ranges from 2.5 eV to 4 eV.

The photovoltaic cell of the present invention uses the first bandgap layer made of a narrow bandgap material and the third bandgap layer made of a wide bandgap material to form a structure with the bandgap gradient so as to reduce the reflection of solar spectrum and enhance the possibility of incident light being absorbed by the component.

Moreover, an extremely thin film having an about angstrom-scaled thickness and bandgap energy between the wide bandgap and the narrow bandgap is used as the second bandgap layer to resolve the problem that the difference of lattice mismatch between the first bandgap layer and the third bandgap layer is excessively large and to reduce the effect of interior defects.

Until the component is irradiated, photo-generated currents can be easily generated from the interface between the first bandgap layer and the third bandgap layer and pass through the second bandgap layer by tunneling effect. In the structure, the recombination of carriers in the interior of the component can be efficiently reduced and the output photocurrent of the solar cell can be increased, resulting in enhancement of photoelectric conversion efficiency of the solar cell.

Hereinafter, the present invention will be described in detail with reference to one or more exemplary embodiments. Other features and advantages of the present invention will become more apparent from the summary of the invention, the preferred embodiments and claims.

The above summary and the following detailed description can be understood through exemplary embodiments and provide further explanation of the scope claimed by the present invention.

### BRIEF DESCRIPTION OF THE DRAWINGS

FIG. 1 shows a conventional solar cell in a P-N junction structure;

FIG. 2 shows a conventional solar cell with no N layer;

FIGS. 3(a) to 3(d) show a process for fabricating a photovoltaic cell according to one preferred embodiment of the present invention;

FIG. 4 shows a bandgap gradient diagram according to one preferred embodiment of the present invention; and

FIG. 5 shows a current vs. voltage diagram under irradiation according to one preferred embodiment of the present invention.

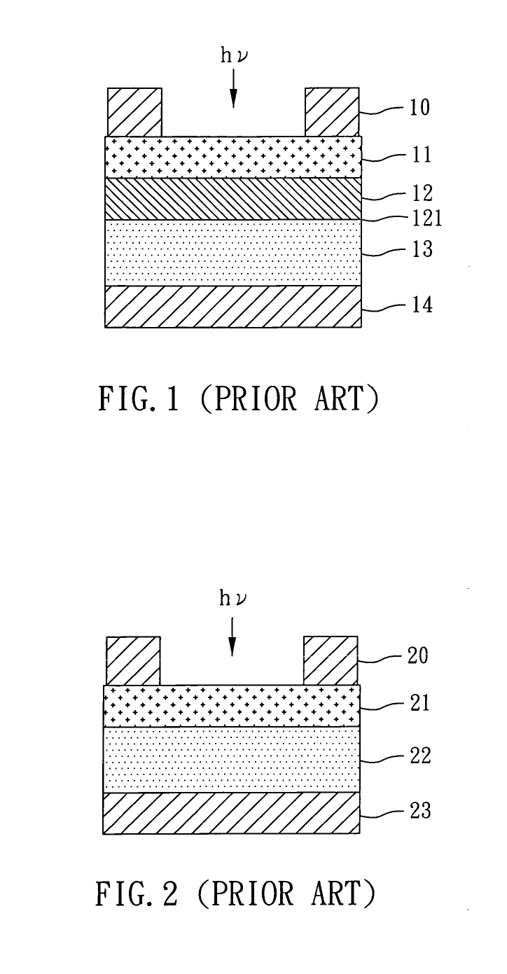

### DETAILED DESCRIPTION OF THE PREFERRED EMBODIMENT

Exemplary embodiments will now be described in detail with reference to the accompanying drawings to make the Examiner be aware of features and effects of the present invention. In all drawings, the same reference numerals in the drawings denote identical or like elements, and thus their description will be omitted.

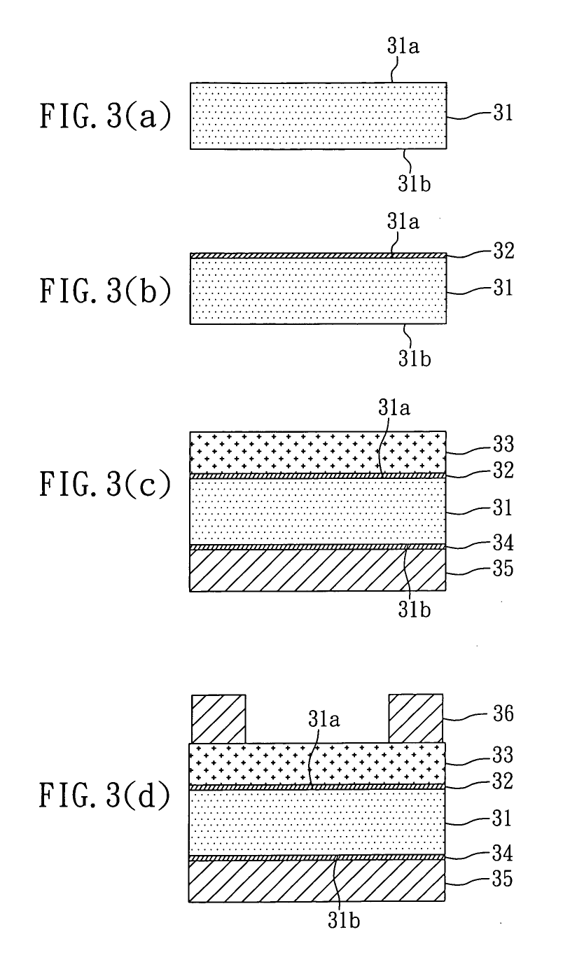

FIGS. 3(a) to 3(d) show a process for fabricating a photovoltaic cell according to one embodiment of the present invention. The photovoltaic cell includes:

a first bandgap layer 31 having a first surface 31a and a second surface 31b, in which a P-type silicon wafer is used and the bandgap of the P-type silicon wafer is 1.12 eV;

a second bandgap layer 32, which is a semiconductor film with a thickness of about 10 Å and may be an amorphous silicon film selected from anyone of an intrinsic semiconductor, an N-type semiconductor and a P-type semiconductor but is not limited to an amorphous silicon film, in which other similar films with a similar bandgap or a bandgap between the first bandgap layer 31 and the following third bandgap layer 33 may be used, and the second bandgap layer 32 is deposited on the first surface 31a of the first bandgap layer 31 via a chemical vapor deposition system and has a bandgap of about 1.7 eV;

a third bandgap layer 33, which includes a wide bandgap material and may be a transparent conducting oxide including but not being limited to anyone of AZO, ITO, CTO, ZnO:Al, ZnGa₂O4, SnO₂:Sb, Ga₂O₃:Sn, AgInO₂:Sn, In₂O₃: Zn, CuAlO₂, LaCuOS, NiO, CuGaO₂ and SrCu₂O₂, in which the transparent conducting oxide is preferably AZO having a bandgap of about 3.4 eV but not limited thereto, and other similar wide bandgap conductive materials with a similar bandgap or a bandgap larger than that of the second bandgap layer 32 may be used, therewith the third bandgap layer 33 being deposited on the second bandgap layer 32 via a physical vapor deposition system;

a back electrode 35, which is deposited over the second surface 31b of the first bandgap layer 31 by evaporation; and

a finger electrode 36, which is formed on the third bandgap layer 33 by conventional photolithography and etching or screen printing and jointed to the third bandgap layer 33.

The materials of the back electrode 35 and the finger electrode 36 may be selected from metals with good conductivity, such as Au, Ag, Cu, Sn, Pb, Hf, W, Mo, Nd, Ti, Ta, Al, Zn or an alloy thereof. Preferably, a back surface field 34 is formed between the back electrode 35 and the second surface 31b of the first bandgap layer 31. More preferably, the back surface field 34 is formed by performing a furnace process on the back electrode 35.

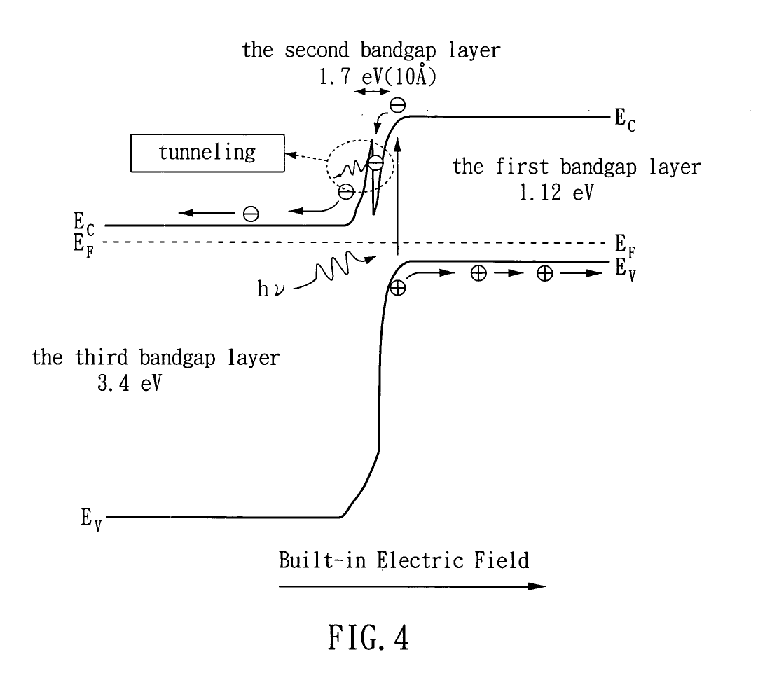

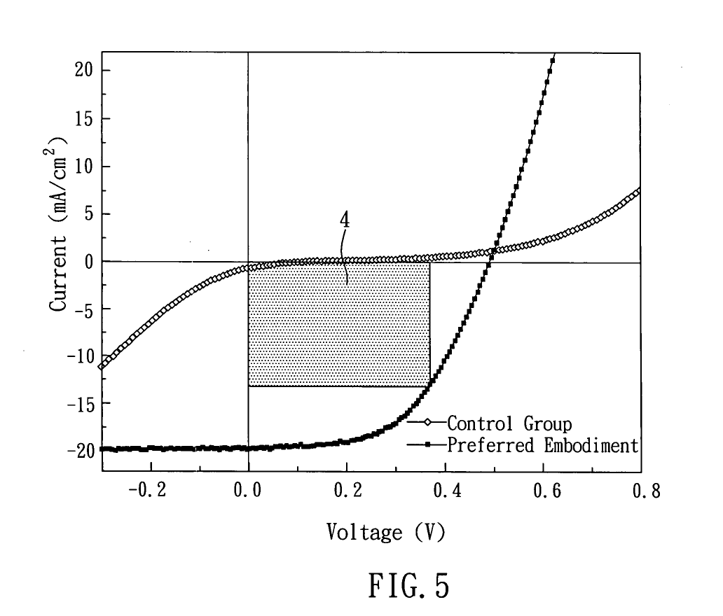

FIG. 4 shows a bandgap gradient diagram according to one embodiment of the present invention. Under irradiation, carriers generated from the interface can pass through the second bandgap layer 32 by tunneling effect, and decreased defects resulting from the reduced thickness of the second bandgap layer 32 can reduce recombination. Additionally, the AZO-containing third bandgap layer 33 disposed on the surface of the second bandgap layer 32 can allow more incident photons to enter the interior of the solar cell to enhance the output photocurrent of the solar cell, resulting in the enhancement of energy conversion efficiency of the solar cell. FIG. 5 shows a current vs. voltage diagram under irradiation according to one embodiment of the present invention.

Energy conversion efficiency of a solar cell refers to a ratio of the maximum output electric power (Pₘₐₓ) converted from the power of incident sunlight (Pᵢₙ), as shown in the following equation:

$$η = \frac{{P}_{ma x}}{{P}_{i n}} = \frac{{I}_{m ax} {V}_{ma x}}{{P}_{i n}} .$$

Output power of a solar cell is the product of current and voltage, as shown in the following equation:

$$P = IV = {I}_{S} V ( {e}^{\frac{qV}{{K}_{B} T }} - 1 ) - {I}_{L} V .$$

It is apparent that output power of a solar cell is not a constant value and the maximum output power can be obtained at a certain current-voltage point with dP/dV=0. The maximum output power of a solar cell is determined by the following equation:

$${P}_{ma x} = {I}_{ma x} {V}_{ma x} ≅ {I}_{L} [ {V}_{OC} - \frac{kT}{q} ln ( 1 + \frac{{qV}_{ma x}}{kT} ) - \frac{kT}{q} ] .$$

Accordingly, the conversion efficiency is determined by the following equation:

$$η = \frac{{I}_{ma x} {V}_{ma x}}{{P}_{m ax }} = \frac{{I}_{L} [ {V}_{OC} - \frac{kT}{q} ln ( 1 + \frac{{qV}_{ma x}}{kT} ) - \frac{kT}{q} ]}{{P}_{ma x}} or η = \frac{FF \cdot {I}_{L} {V}_{OC}}{{P}_{m ax}} .$$

Herein, FF (fill factor) is a ratio of output power Pₘₐₓ to the product of open circuit voltage V_{oc} and short circuit current I_{sc} under maximum output power. That is, FF is a ratio of the maximum power rectangle area (the area 4) of the solar cell I-V characteristics to the rectangle area of V_{oc}×I_{sc}. The following table 1 shows the conversion efficiency according to the preferred embodiment and the control group.

TABLE 1
Conversion Efficiency of Preferred
Embodiment and Control Group

| | V_{oc} | I_{sc} | FF | η |
|---|---|---|---|---|
| Sample | (V) | (mA/cm²) | (%) | (%) |
| Control Group | 0.14 | 0.68 | 16.22 | 0.016 |
| Preferred Embodiment | 0.49 | 19.75 | 53.53 | 5.18 |

As showed in the above table, the output photocurrent of the solar cell according to the preferred embodiment is increased, resulting in the increase of the conversion efficiency (η) of the solar cell.

In conclusion, the present invention uses a wide bandgap material and a narrow bandgap material to form a structure with a bandgap gradient, such that most photons can achieve the narrow bandgap layer and thus the absorption of photons in the interface depletion region between the wide bandgap layer and the narrow bandgap layer can be enhanced without an N layer. Meanwhile, the utilization of the second bandgap layer 32 made of a semiconductor film can prevent junction defects and recombination of photo-generated carriers caused by heterojunction lattice mismatch. Accordingly, the present invention complies with the criterion of novelty and inventive step.

### Other Examples

All features described in the present specification can be combined in any manner and can be displaced with others for identical, equivalent or similar purposes. Thereby, without specific explanations, each disclosed features should be construed as being exemplary embodiments for identical or similar features. Through the above description, those skilled in the art can easily be aware of essential features of the present invention and understand that many other possible modifications and variations for various purposes or conditions can be made without departing from the spirit and scope of the invention as hereinafter claimed. Those having ordinarily knowledge in the art can easily modify or replace the wafer layer, the wide bandgap material, the semiconductor film, the electrode disclosed in various preferred examples without departing from the spirit and scope of the invention. Thereby, the present invention should not be limited to the invention claimed in the accompanying claims and equivalents thereof. Accordingly, other embodiments should be within the scope of the accompanying claims.

All patents and documents mentioned in the present specification can show the level of ordinary skill in the art. All patents and documents mentioned in the present specification are incorporated herein by reference in its entirety.

What is claimed is:

1. A photovoltaic cell comprising:
a first bandgap layer, which is a silicon wafer and has a first surface and a second surface;
a second bandgap layer, which is a semiconductor film with a thickness of 1˜100 Å and a greater bandgap than that of the first bandgap layer and is disposed on the first surface of the first bandgap layer;
a third bandgap layer, which comprises a wide bandgap material and a greater bandgap than that of the second bandgap layer and is disposed on the second bandgap layer;
a back electrode, which is jointed to the second surface of the first bandgap layer; and
a finger electrode, which is disposed on the third bandgap layer and jointed to the third bandgap layer.

2. The photovoltaic cell as claimed in claim 1, wherein the silicon wafer is a P-type silicon wafer.

3. The photovoltaic cell as claimed in claim 1, wherein the semiconductor film is an amorphous silicon film.

4. The photovoltaic cell as claimed in claim 1, wherein the semiconductor film is anyone of an intrinsic semiconductor, an N-type semiconductor and a P-type semiconductor.

5. The photovoltaic cell as claimed in claim 1, wherein the second bandgap layer ranges from 1 Å to 50 Å in thickness.

6. The photovoltaic cell as claimed in claim 5, wherein the second bandgap layer ranges from 1 Å to 10 Å in thickness.

7. The photovoltaic cell as claimed in claim 1, wherein the third bandgap layer is made of a transparent conducting oxide.

8. The photovoltaic cell as claimed in claim 7, wherein the transparent conducting oxide is anyone of AZO, ITO, CTO, ZnO:Al, ZnGa₂O₄, SnO₂:Sb, Ga₂O₃:Sn, AgInO₂:Sn, In₂O₃: Zn, CuAlO₂, LaCuOS, NiO, CuGaO₂ and SrCu₂O₂.

9. The photovoltaic cell as claimed in claim 8, wherein the transparent conducting oxide is AZO.

10. The photovoltaic cell as claimed in claim 1, wherein a back surface field is formed between the back electrode and the second surface of the first bandgap layer.
